(19) United States
(12) Patent Application Publication
(10) Pub. No.: US 2026/0019056 A1
(43) Pub. Date: Jan. 15, 2026

(54) AUDIO POWER AMPLIFIER CIRCUIT AND DUTY CYCLE MODULATION CIRCUIT AND NOISE SUPPRESSION CIRCUIT THEREOF

(71) Applicant: SHANGHAI SG MICRO CO., LTD., Shanghai (CN)

(72) Inventors: He LIU, Shanghai (CN); Xiang YU, Shanghai (CN)

(21) Appl. No.: 19/106,045

(22) PCT Filed: Jul. 17, 2023
(86) PCT No.: PCT/CN2023/107684

§ 371 Date: Sep. 18, 2025

(30) Foreign Application Priority Data
Aug. 24, 2022 (CN) 202211020372.1

(51) Int. Cl. H03G 3/34; H03F 3/21; H04R 3/02

(52) U.S. Cl. CPC H03G 3/344; H03F 3/21; H04R 3/02; H03F 2200/03; H04R 2430/01

(57) ABSTRACT

An audio power amplifier circuit and a duty cycle modulation circuit and a noise suppression circuit thereof are disclosed. The audio power amplification circuit includes an integral amplifier module and a high frequency switch The duty cycle modulation circuit is used to adjusts a gain of the audio power amplifier circuit by controlling a duty cycle of the high frequency switch. The duty cycle modulation circuit counts pulses of a duty cycle modulation signal to obtain a first count value counts pulses of a clock signal to obtain a second counting value and performs a logical operation according to the first count value, the second count value, and the clock signal to obtain a switch modulation signal for controlling the high frequency switch. The “pop” noise is weakened by controlling the gain of the audio power amplifier circuit, and the cost is reduced while meeting the high linearity of the circuit.

### Cross-reference to related applications

This application is a Section 371 National Stage Application of International Application No. PCT/CN2023/107684, filed on Jul. 17, 2023, and published as WO2024/041267A1, published Feb. 29, 2024, not in English, which claims priority to the Chinese Patent Application No. 202211020372.1, filed on Aug. 24, 2022, entitled “audio power amplifier circuit and duty cycle modulation circuit and noise suppression circuit thereof”, which are incorporated herein by reference in its entirety in this disclosure, including the specification, claims, drawings and abstract.

### TECHNICAL FIELD

The present disclosure relates to a technical field of audio power amplifiers, and more particularly, to an audio power amplifier circuit and a duty cycle modulation circuit and a noise suppression circuit thereof.

### BACKGROUND

A D-type amplifier circuit is a switch-type power amplifier circuit, which has characteristics of high efficiency and less heat generation compared with linear power amplifier circuit, so it is often used as an audio power amplifier circuit in a field of consumer electronics such as smart TVs and mobile phones.

FIG. 1 shows a schematic circuit diagram of a two-stage audio power amplifier circuit in a prior art. As shown in FIG. 1, the audio power amplifier circuit 100 includes an integral amplifier module 110, a signal modulation module 120, and a drive output module 130.

The integral amplifier module 110 includes a first-stage integral amplifier AMP1 and a second-stage integral amplifier AMP2. A pair of differential signals INA and INB are coupled to inputs of the first-stage integral amplifier AMP1 through capacitance Cin and resistor Rin, respectively, and are sequentially fully differentially amplified by the first-stage integral amplifier AMP1 and the second-stage integral amplifier AMP2 to obtain output signals OPA and OPB. The output signals OPA and OPB are modulated with a modulation signal RAMP by a comparator CMP1 and a comparator CMP2 in the signal modulation module 120, respectively, so as to generate pulse width modulation signals PWMA and PWMB. The drive output module 130 amplifies power of the pulse width modulation signals PWMA and PWMB through alternating operation of a transistor half-bridge, so as to generate drive signals OUTA and OUTB. The feedback resistors Rfb1 and Rfb2 are used to feedback the drive signals OUTA and OUTB to an input terminal. In practical applications, the drive signal output by the drive output module 130 could be transmitted directly to a speaker to be restored as an audio signal (the speaker itself has a certain low-pass filtering capability) or reduced to an audio signal through a low-pass filter circuit for transmission to the speaker for playback.

Existing audio power amplifier circuits produce “pop” noise at the output when the device is powered on or off. The “pop” noise will cause the speaker to produce bursting sound when the power amplifier is powered up or shut down. Small “pop” noises could make the user feel uncomfortable, and loud “pop” noises are more likely to damage the speaker. Therefore, how to suppress the “pop” noise of the audio power amplifier circuit is very important.

### SUMMARY

In view of the above problems, an object of the present disclosure is to provide an audio power amplifier circuit and a duty cycle modulation circuit and a noise suppression circuit thereof. By controlling a gain of the audio power amplifier circuit to weaken the “pop” noise during a process of turning on or off the chip, a high linearity of the circuit is met with the cost being reduced.

According to a first aspect of the present disclosure, there is provided a duty cycle modulation circuit of an audio power amplifier circuit. The audio power amplifier circuit comprises an integral amplifier module and a high frequency switch disposed between input resistors of a second-stage integral amplifier in the integral amplifier module. The duty cycle modulation circuit is configured to adjust a gain of the audio power amplifier circuit by controlling a duty cycle of the high frequency switch. The duty cycle modulation circuit comprises: a first counting module, a second counting module and a logic output module. The first counting module is used for counting pulses of a duty cycle modulation signal to obtain a first count value. The second counting module is used for counting pulses of a clock signal to obtain a second count value. The logic output module is used for performing a logical operation according to the first count value, the second count value, and the clock signal to obtain a switch modulation signal for controlling the high frequency switch.

Optionally, the logic output module is configured to determine a pulse width of the switch modulation signal according to the first count value and to determine a switching period of the switch modulation signal according to the second count value.

Optionally, the duty cycle modulation circuit further comprises a first detection module for providing a first detection signal to the logic output module upon the first count value is 0, wherein the logic output module is used for setting the switch modulation signal to an initial level state according to the first detection signal.

Optionally, the duty cycle modulation circuit further comprises a second detection module for providing a second detection signal to the first counting module and the logic output module upon the first counting value reaches a first preset value. The first counting module stops counting the pulses of the duty cycle modulation signal according to the second detection signal, and the logic output module sets the switch modulation signal in a final level state according to the second detection signal.

Optionally, the duty cycle modulation circuit further comprises a third detection module and a first NOR gate. The third detection module for outputting a third detection signal upon the second count value reaches a second preset value. The first NOR gate is used for performing a NOR logical operation on the third detection signal and the first detection signal, and providing a first logical signal to the second counting module. The first NOR gate is configured to reset the second counting module upon one of the first detection signal and the third detection signal is valid.

Optionally, the first counting module comprises a first D flip-flop, a second NOR gate and a first counter. The first D flip-flop has a first data signal input terminal, a first clock control terminal, a first reset terminal and a first signal output terminal, wherein the first data signal input terminal receives the duty cycle modulation signal, the first clock control terminal receives the clock signal, the first reset terminal receives a reset signal, and the first signal output terminal outputs a second logic signal. The second NOR gate is used for performing a NOR logical operation on the second detection signal, the second logic signal, and an inverse signal of the reset signal, and outputting a third logic signal. The first counter has a second clock control terminal, a second reset terminal and a second signal output, wherein the second clock control terminal receives the third logic signal, the second reset terminal receives the reset signal, and the second signal output outputs the first count value.

Optionally, the second counting module comprises: a second counter having a third clock control terminal, a third reset terminal and a third signal output, wherein the third clock control terminal receives the clock signal, the third reset terminal receives the first logic signal, and the third signal output outputs the second count value.

Optionally, the logic output module comprises a logic unit, a second D flip-flop, a third D flip-flop, a third NOR gate and a fourth NOR gate. The logic unit has a first count input terminal, a second count input terminal, a fourth clock control terminal, a fourth reset terminal and a fourth signal output terminal, wherein the first count input receives the first count value, the second count input receives the second count value, the fourth clock control terminal receives the clock signal, the fourth reset terminal receives the reset signal, and the fourth signal output terminal outputs a fourth logic signal. The second D flip-flop has a second data signal input terminal, a fifth clock control terminal, a fifth reset terminal and a fifth signal output terminal, wherein the second data signal input terminal receives a power supply voltage, the fifth clock control terminal receives the fourth logic signal, the fifth reset terminal receives the first logic signal, and the fifth signal output terminal outputs a fifth logic signal. The third D flip-flop has a third data signal input terminal, a sixth clock control terminal, a sixth reset terminal, and a sixth signal output terminal, wherein the third data signal input terminal receives the fifth logic signal, the sixth clock control terminal receives the clock signal, the sixth reset terminal receives an inverse signal of the first detection signal, and the sixth signal output terminal outputs a sixth logic signal. The third NOR gate is used for performing a NOR logical operation on the second detection signal and the sixth logic signal, and outputting a seventh logic signal. The a fourth NOR gate is used for performing a NOR logical operation on the first detection signal and the seventh logic signal, and outputting the switch modulation signal.

Optionally, the logic unit is configured to determine whether the first count value is equal to the second count value before each falling edge of the clock signal comes, and if so, set the fourth logic signal to a logic high level.

Optionally, the first count value and the second count value are constituted by a multi-bit binary number, and the first counter and the second counter include a synchronous counter.

Optionally, the synchronization counter comprises: a plurality of D flip-flops having the same number as bits of the multi-bit binary number, a clock control terminal of a first D flip-flop of the plurality of D flip-flops receiving a counting signal; and a plurality of signal transfer units preceding a second to last D flip-flop of the plurality of D flip-flops, wherein each signal transfer unit is configured to obtain a signal of a clock control terminal of a corresponding D flip-flop according to an output logic state of the D flip-flop before the corresponding D flip-flop and an inverse signal of the counting signal.

Optionally, each signal transfer unit is configured to: determining whether the output logic state of all D flip-flops before the corresponding D flip-flop is at a logic high level, and if so, controlling the signal of the clock control terminal of the corresponding D flip-flop to be the same as the counting signal; otherwise, controlling the signal of the clock control terminal of the corresponding D flip-flop is constantly at the logic high level.

Optionally, the signal transfer unit comprises at least one NAND gate or a combination of at least one NAND gate and an inverter.

Optionally, a frequency of the clock signal is set by a frequency of the switch modulation signal and a duty cycle change linearity required by the system.

Optionally, a frequency of the duty cycle modulation signal is set by a chip power on or off time.

According to a second aspect of the present disclosure, there is provided a noise suppression circuit for an audio power amplifier circuit, wherein the audio power amplifier circuit comprises at least an integral amplifier module, a signal modulation module, and a drive output module, and the noise suppression circuit comprises: a high frequency switch disposed between input resistors of a second-stage integral amplifier in the integral amplifier module; and an above-mentioned duty cycle modulation circuit for adjusting a gain of the audio power amplifier circuit by controlling a duty cycle of the high frequency switch.

According to a third aspect of the present disclosure, there is provided an audio power amplifier circuit comprising an integral amplifier module, a signal modulation module, a drive output module, a high frequency switch and an above-mentioned duty cycle modulation circuit. The integral amplifier module comprises at least a first-stage operational amplifier and a second-stage integral amplifier, for amplifying a differential input signal by an integration operation to obtain a differential output signal. The signal modulation module is used for generating a first pulse width modulation signal and a second pulse width modulation signal according to the differential output signal. The drive output module is used for amplifying the first pulse width modulation signal and the second pulse width modulation signal, respectively, so as to obtain a drive signal for driving a speaker. The high frequency switch is disposed between input resistors of the second-stage integral amplifier in the integral amplifier module. The above-mentioned duty cycle modulation circuit is used for adjusting the gain of the audio power amplifier circuit by controlling a duty cycle of the high frequency switch.

The audio power amplifier circuit of the embodiment of the present disclosure includes a high frequency switch and a duty cycle modulation circuit arranged between the input resistors of the second-stage integral amplifier of the integral amplifier module. During the process of turning on or off the chip, the duty cycle modulation circuit generates a switch modulation signal of the high frequency switch by counting the duty cycle modulation signal and the clock signal, so that the duty cycle of the high frequency switch could be gradually reduced or increased according to a set linearity, so as to regulate the gain of the audio power amplifier circuit. Not only the “pop” noise could be weakened, but also the linearity of the circuit could be improved, and the cost of the circuit could be reduced.

In a further embodiment, the present disclosure further provides a synchronization counter for counting. By setting the signal transfer unit, before the clock control signal is sent to each D flip-flop in the counter, the counter can prejudge whether output signal of all D flip-flops before this D flip-flop is at a logic high level. If the output signal of all D flip-flops before the D flip-flop is at the logic high level, the clock control signal for controlling this D flip-flop is the same as the counting signal, and conversely, the clock control signal of this D flip-flop is set to the logic high level, so that the output delay of the counter could be only a delay of one D flip-flop, and the delay of the counter is greatly reduced.

### BRIEF DESCRIPTION OF THE DRAWINGS

The foregoing and other objects, features and advantages of the present disclosure will become clearer by the following description of embodiments of the present disclosure with reference to the accompanying drawings.

FIG. 1 shows a schematic circuit diagram of a two-stage audio power amplifier circuit in a prior art.

FIG. 2 shows a schematic circuit diagram of an audio power amplifier circuit with noise suppression function according to an embodiment of the present disclosure;

FIG. 3 shows a schematic circuit diagram of a duty cycle modulation circuit according to an embodiment of the present disclosure;

FIG. 4 shows an operating timing diagram of a duty cycle modulation circuit according to an embodiment of the present disclosure;

FIG. 5 shows an operating timing diagram of a first counting module according to an embodiment of the present disclosure;

FIG. 6 shows a schematic circuit diagram of a synchronization counter according to an embodiment of the present disclosure.

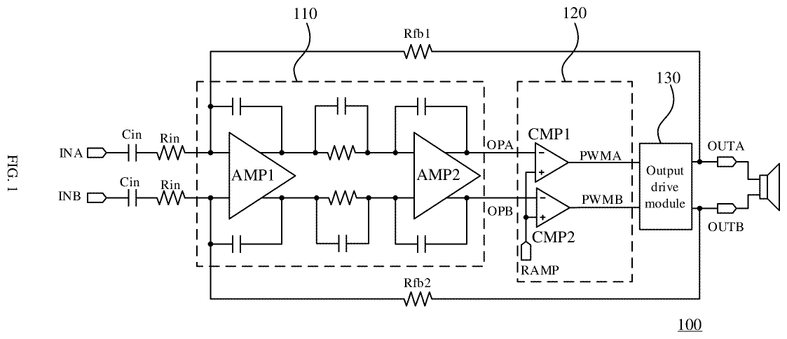

### DETAILED DESCRIPTION OF THE DISCLOSURE

The present disclosure is described below based on examples, but the present disclosure is not limited to these examples. In the following detailed description of the disclosure, some specific parts of details are described in detail. The present disclosure could be fully understood without a description of these details to those skilled in the art. To avoid confusing the essence of the disclosure, well-known method, process, procedure, element, and circuit are not described in detail.

Furthermore, it should be understood by those of ordinary skill in the art that the drawings provided herein are for illustrative purposes only and that they are not necessarily drawn to scale.

It should be understood that in the following description, the word “circuit” refers to a conductive circuit consisting of at least one element or sub-circuit through electrical coupling or electromagnetic coupling. When an element or a circuit is said to be “connected” to another element or an element/circuit is said to be “connected” between two nodes, it may be directly coupled or connected to another element or there may be an intermediate element, and the connection between the elements may be physical, logical, or a combination thereof. Conversely, when the element is said to be “directly coupled” or “directly connected” to another element, it means that there is no intermediate element between the two.

The present disclosure is further described below in connection with the accompanying drawings and embodiments.

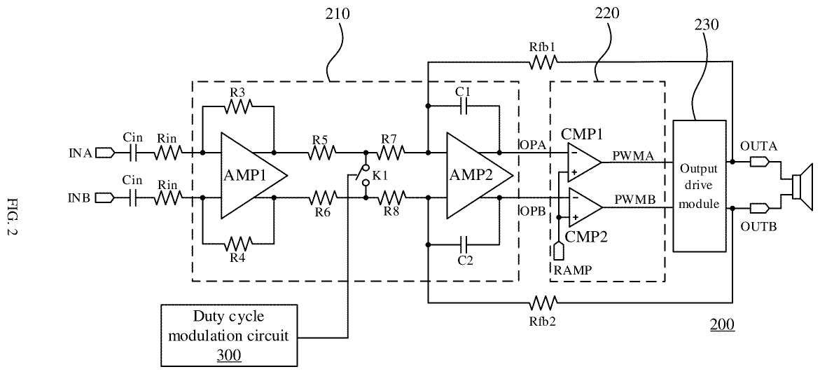

FIG. 2 shows a schematic circuit diagram of an audio power amplifier circuit with noise suppression function according to an embodiment of the present disclosure; As shown in FIG. 2, the audio power amplifier circuit 200 includes an integral amplifier module 210, a signal modulation module 220, a drive output module 230, a high frequency switch K1, and a duty cycle modulation circuit 300.

Wherein, the integral amplifier module 210 includes a first-stage operational amplifier AMP1 and a second-stage integral amplifier AMP2. A pair of differential input signals INA and INB are respectively coupled to inputs of the first-stage operational amplifier AMP1 through input a capacitor Cin and an input resistor Rin, and are fully differentially amplified by the first-stage operational amplifier AMP1 and the second-stage integral amplifier AMP2 in turn to obtain differential output signals OPA and OPB. The differential input signals INA and INB are converted into current signals through the resistors and input to the first stage operational amplifier AMP1, so as to output voltage signals after amplification by the first stage operational amplifier AMP1. The voltage signals are converted into current signals by resistors R5 to R8 and input to the second-stage integral amplifier AMP2, so as to output differential output signals OPA and OPB after integration amplification by the second-stage integral amplifier AMP2. The differential output signals OPA and OPB are voltage signals. Further, feedback resistors R3 and R4 are arranged between the input terminals and output terminals of the first stage operational amplifier AMP1. Integration capacitors C1 and C2 are arranged between differential input terminals and differential output terminals of the second-stage integral amplifier AMP2. The signal modulation module 220 is used to receive the differential output signals OPA and OPB that are corrected, respectively, and generate a first pulse width modulation signal PWMA and a second pulse width modulation signal PWMB according to the differential output signals OPA and OPB. Wherein, the first pulse width modulation signal PWMA is obtained by modulating the differential output signal OPA, and the second pulse width modulation signal PWMB is obtained by modulating the differential output signal OPB. Specifically, the signal modulation module 220 may include two parallel comparators CMP1 and CMP2. The comparator CMP1 is used to compare the differential output signal OPA and the modulation signal RAMP, and output the first pulse width modulation signal PWMA. The comparator CMP2 is used to compare the differential output signal OPB and the modulation signal RAMP, and output the second pulse width modulation signal PWMB. The modulation signal RAMP is usually a waveform with periodic tilt rising and tilt falling edges such as a triangular wave or a sawtooth wave. Therefore, two differential signals could be conveniently modulated into PWM signals. Of course, the signal modulation module 220 may perform the PWM modulation by use of a circuit with other structure.

The drive output module 230 is used to amplify the first pulse width modulation signal PWMA and the second pulse width modulation signal PWMB, respectively, so as to obtain the drive signals OUTA and OUTB. The drive output module 230 may include a half-bridge circuit including two transistors connected in series between a power supply and ground. When an input pulse width modulation signal is at a high level, the transistor connected to the power supply is turned on and the transistor connected to the ground is turned off, so as to output a voltage and current limited by the power supply. When the input pulse width modulation signal is at a low level, the transistor connected to the ground is turned on, and the transistor connected to the power supply is turned off, so that the PWM signal could be amplified. It should be noted that the integral amplifier module 210 and the signal modulation module 220 of the present embodiment usually use a low-voltage domain power supply VDD generated by a low-voltage differential linear regulator (LDO) (not shown in the figure) inside the chip to supply power, the VDD is typically about 4V to 6V. The power supply of the drive output module 230 usually adopts a high-voltage domain power supply PVDD (not shown in the figure) provided by outside of the chip, which can be as low as 4V and up to 30V, typically about 20V to 30V.

Further, the audio power amplifier circuit 200 of the present embodiment further includes a feedback circuit connected between a differential output terminal of the drive output module 230 and the differential input terminal of the second-stage integral amplifier AMP2. Specifically, the feedback circuit includes two feedback resistors Rfb1 and Rfb2. wherein the feedback resistor Rfb1 is connected between a first output terminal of the drive output module 230 and a first input terminal of the second-stage integral amplifier AMP2, and the feedback resistor Rfb2 is connected between a second output terminal of the drive output module 230 and a second input terminal of the second-stage integral amplifier AMP2.

In the present embodiment, the high frequency switch K1 is arranged between the input resistors R5 to R8 of the second-stage integral amplifier AMP2 in the integral amplifier module 210. The duty cycle modulation circuit 300 is used to generate a switch signal that controls on and off of the high frequency switch K1. A duty cycle of the high frequency switch K1 is controlled by controlling a duty cycle of the switch signal to regulate a gain of the audio power amplifier circuit 200, thereby attenuating the “pop” noise.

In the present embodiment, before the chip is turned on, the duty cycle modulation circuit 300 generates a duty cycle of 100% of the control signal of the high frequency switch K1, that is, the high frequency switch K1 remains on, at which time the gain of the circuit is 0, and then the duty cycle modulation circuit 300 gradually reduces the duty cycle of the high frequency switch K1 according to the set linearity until the duty cycle of the switch signal is 0, at which time the gain of the circuit reaches a normal gain. When the chip is turned off, the duty cycle modulation circuit 300 gradually increases the duty cycle of the high frequency switch according to the set linearity until the duty cycle of the high frequency switch K1 reaches 100%.

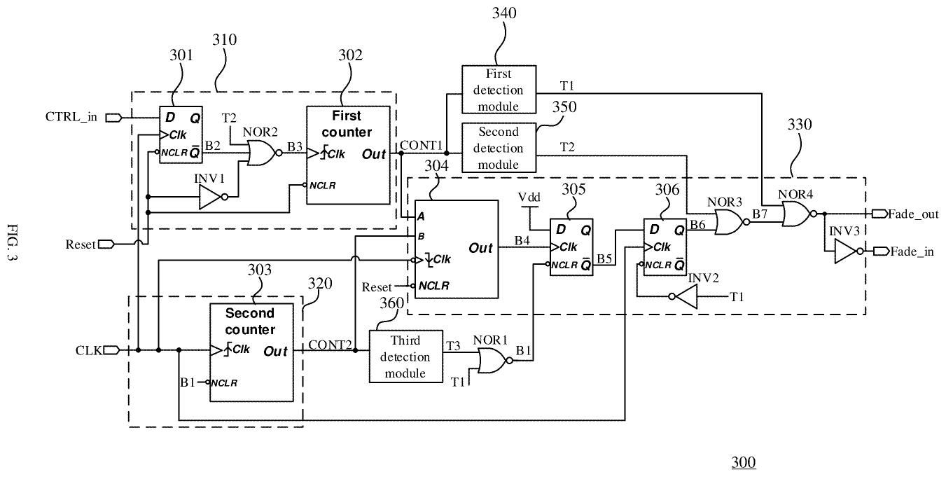

FIG. 3 shows a schematic circuit diagram of a duty cycle modulation circuit 300 according to an embodiment of the present disclosure. As shown in FIG. 3, the digital duty cycle modulation circuit 300 of the present embodiment includes a first counting module 310, a second counting module 320, a logic output module 330, a NOR gate NOR1, a first detection module 340, a second detection module 350 and a third detection module 360.

The first counting module 310 is used to receive a duty cycle modulation signal Ctrl_in and count pulses of the duty cycle modulation signal Ctrl_in to obtain a first count value CONT1. The second counting module 320 is used to count pulses of a clock signal CLK and obtains a second counting value CONT2. Wherein, the first count value CONT1 and the second count value CONT2 are, for example, multi-bit binary numbers. The logic output module 330 is used to perform a logical operation according to the first count value CONT1, the second count value CONT2, and the clock signal CLK, so as to output switch modulation signals Fade_in and Fade_out. Wherein, the switch modulation signal Fade_in is used to control a duty cycle change of the high frequency switch K1 during a chip power on process, and the switch modulation signal Fade_out is used to control a duty cycle change of the high frequency switch K1 during a chip power off process. In the present embodiment, the switch modulation signals Fade_in and Fade_out are inverted to each other.

Wherein, the duty cycle of the switch modulation signal refers to a ratio of high level time to a switching period. The logic output module 330 is configured to determine a pulse width (i.e., high level time) of the switch modulation signals Fade_in and Fade_out according to the first count value CONT1, and to determine a switching period of the switch modulation signals Fade_in and Fade_out according to the second count value CONT2, so that the duty cycle of the switch modulation signal could be controlled.

The first detection module 340 is used to detect the first count value CONT1, which is configured to output a first detection signal T1 to the logic output module 330 when the first count value CONT1 is 0. The second detection module 350 is used to detect the first count value CONT1, which is configured to output a second detection signal T2 to the logic output module 330 when the first count value CONT1 reaches a first preset value. The third detection module 360 is used to detect the second count value CONT2, which is configured to output a third detection signal T3 when the second count value CONT2 reaches a second preset value. One input terminal of the NOR gate NOR1 is used to receive the third detection signal T3, the other input terminal is used to receive the first detection signal T1, and an output is used to provide a logic signal B1 to the logic output module. wherein the first preset value is used to define a total time period of the chip power on process or power off process, and the second preset value is used to define a switching period of the switch modulation signal.

Specifically, the first counting module 310 includes a D flip-flop 301, a NOR gate NOR2, an inverter INV1, and a first counter 302.

Wherein, the D flip-flop 301 has a data signal input terminal D, a clock control terminal Clk, a reset terminal NCLR (also known as a zeroing terminal), and signal output terminals Q and QN. The data signal input terminal D of the D flip-flop 301 is used to receive the duty cycle modulation signal Ctrl_in. The clock control terminal Clk is connected to the clock signal CLK. The reset terminal NCLR is connected to the reset signal Reset. The signal output terminal QN is used to output the logic signal B2. A first input terminal of the NOR gate NOR2 is used to receive the second detection signal T2, a second input terminal is connected to the signal output terminal QN of the D flip-flop 301 to receive the logic signal B2, and a third input terminal is connected to an output terminal of the inverter INV1 to receive an inverse signal of the reset signal Reset. The first counter 302 has a clock control terminal Clk, a reset terminal NCLR, and an output terminal Out. The clock control terminal is connected to the output terminal of the NOR gate NOR2 to receive the logic signal B3. The reset terminal NCLR is connected to the reset signal Reset. The output terminal Out is used to output the first count value CONT1.

The second counting module 320 includes a second counter 303. The second counter 303 has a clock control terminal Clk, a reset terminal NCLR, and an output terminal Out. Wherein, the clock control terminal Clk of the second counter 303 is connected to the clock signal CLK, the reset terminal NCLR is connected to the output terminal of the NOR gate NOR1, and the output terminal Out is used to output the second count value CONT2.

The logic output module 330 includes logic units 304, D flip-flops 305 and 306, NOR gates NOR3 and NOR4, and inverters INV2 and INV3. Wherein, the logic unit 304 has count input terminals A and B, a clock control terminal Clk, a reset terminal NCLR, and an output terminal Out, wherein the count input terminal A is used to receive the first count value CONT1, the count input terminal B is used to receive the second count value CONT2, the clock control terminal Clk is used to receive the clock signal CLK, the reset terminal NCLR is used to receive the reset signal Reset, and the output terminal Out is used to output a logic signal B4. The data signal input terminal D of the D flip-flop 305 is used to receive a power supply voltage Vdd, the clock control terminal Clk is connected to the output terminal of the logic unit 304 to receive the logic signal B4, the reset terminal NCLR is connected to an output terminal of the NOR gate NOR1, and the signal output terminal QN is used to output a logic signal B5. The data signal input terminal D of the D flip-flop 306 is connected to the signal output terminal QN of the D flip-flop 305 to receive the logic signal B5. The clock control terminal Clk receives the clock signal CLK. The reset terminal NCLR is connected to the output terminal of the inverter Inv2 to receive an inverse signal of the first detection signal T1. The signal output terminal Q is used to output a logic signal B6. One input temrinal of the NOR gate NOR3 is connected to the output terminal of the second detection module 350 to receive the second detection signal T2, and the other input is connected to the signal output terminal Q of the D flip-flop 306 to receive the logic signal B6. One input terminal of the NOR gate NOR4 is connected to the output terminal of the first detection module 340 to receive the first detection signal T1, and the other input terminal is connected to the output terminal of the NOR gate NOR3 to receive the logic signal B7, and the output terminal is used to output the switch modulation signal Fade_out. The input terminal of the inverter INV3 is connected to the output terminal of the NOR gate NOR4, and the output terminal of the inverter INV3 is used to output the switch modulation signal Fade_in.

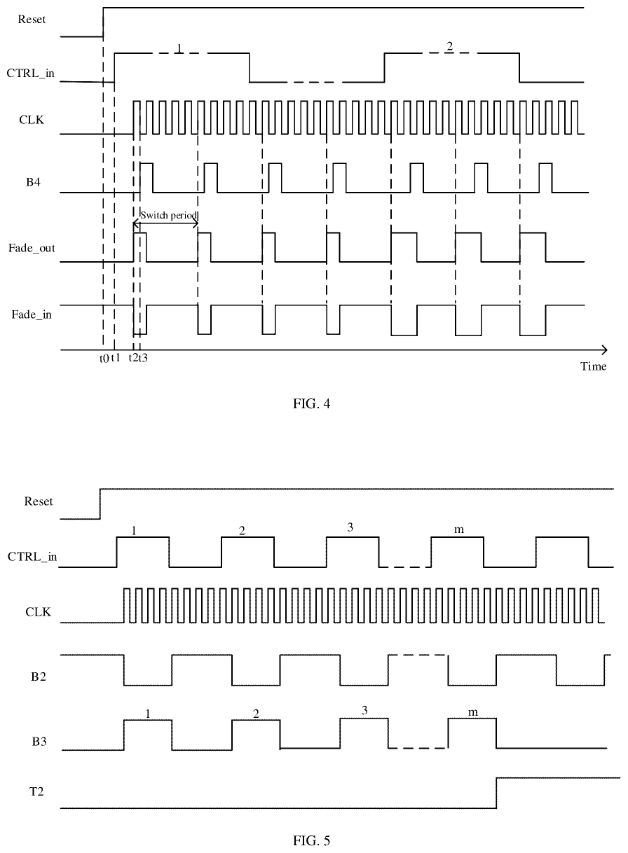

FIG. 4 shows an operating timing diagram of a duty cycle modulation circuit according to an embodiment of the present disclosure, in which timing diagrams of the reset signal Reset, the duty cycle modulation signal Ctrl_in, the clock signal CLK, the output signal B4 of the logic unit 304, and the switch modulation signals Fade_in and Fade_out are shown, respectively. An operating principle of the duty cycle modulation circuit of the embodiment of the present disclosure will be described in detail below with reference to FIGS. 3 and 4, taking the chip power off process as an example.

First, a frequency of the input clock signal CLK is configured according to a frequency of the switch modulation signal Fade_out and a linearity of a duty cycle change required by a system. Assuming that an output frequency of the switch modulation signal Fade_out is 1M and the linearity of the duty cycle change that is required is 1%, the frequency of the input clock signal CLK is: 1M/1%=100M. Then, the frequency of the duty cycle modulation signal Ctrl_in is configured according to a time requirement of the switch modulation signal Fade_out. Assuming that a time of the chip power off process is 10 ms, the period of the duty cycle modulation signal Ctrl_in is: 10 ms/100=0.1 ms.

In the present embodiment, the D flip-flop, the counter, and the reset terminal NCLR of the logic unit in the circuit are effective at a low level. Before time t0, the reset signal Reset is set to a logic low level, each module in the circuit is reset, and the output of the first counter 302 is reset to zero. At this time, the first detection signal T1 output by the first detection module 340 is flipped to a logic high level, and the switch modulation signal Fade_out is set to an initial level state, that is, the logic low level (at this time, the duty cycle of the switch modulation signal Fade_out is 0). At the same time, reset the second counter 303, the D flip-flop 305, and the D flip-flop 306. After the time t0, the reset signal Reset is set to the logic high level, and each module in the circuit exits the reset state. At time t1, a pulse signal Ctrl_in is input through a duty cycle modulation pin, and at the same time, the pulse of the duty cycle modulation signal Ctrl_in is counted by the first counting module 310, at which time a value of the first counting value CONT1 is <000 . . . 001>.

FIG. 5 shows a operating timing diagram of a first counting module according to an embodiment of the present disclosure; As shown in FIG. 5, when the reset signal Reset is at the logic high level, the D flip-flop 301 determines a logic state of the output signal B2 according to a logic state of the duty cycle modulation signal Ctrl_in at the data signal input terminal D before each rising edge of the clock signal CLK, so that a waveform of the logic signal B2 is obtained. Since the second detection signal T2 and an output signal of the inverter INV1 are both low at this time, the waveform of the logic signal B3 output by the NOR gate NOR2 is completely opposite to the logic signal B2. The first counter 302 is efficient before each rising edge of the logic signal B3 and counts pulses of the signal B3, so as to output the first count value CONT1. Since the phase of the signal B3 is the same as that of the duty cycle modulation signal Ctrl_in, the first counter 302 counts the pulses of the duty cycle modulation signal Ctrl_in. When the value of the first count value CONT1 reaches a first preset value m (for example, m=100, the linearity requirement of 100 pulses of the duty cycle modulation signal Ctrl_in corresponding to the duty cycle change of the switch modulation signal is 1%), the second detection signal T2 output by the second detection module 350 is flipped to the logic high level, at this time, the output signal B3 of the NOR gate NOR2 is flipped to the logic low level, and the first counter 302 stops counting the pulse.

Continuing with FIG. 4, when the second detection signal T2 is at the logic high level, the output signal B7 of the NOR gate NOR3 is flipped to the logic low level. Since the first count value CONT1 is not 0 after the first counting module 310 starts counting, at this time, the first detection signal T1 is also at the logic low level. Then the output signal of the NOR gate NOR4 is set to the logic high level, so that the switch modulation signal Fade_out is set to the logic high level (at this time, the duty cycle of the switch modulation signal Fade-out is 100%). When the value of the first count value CONT1 is greater than 0 and less than the first preset value, the second counter 303 starts to work, counts the pulses of the clock signal CLK, and outputs the second count value CONT2. At time t2, when the rising edge of each cycle of the clock signal CLK arrives, the D flip-flop 306 outputs the logic high level at the signal output terminal QN of the flip-flop 305 in a reset stage D to the signal output Q, the NOR gate NOR3 sets the signal B7 to the logic low level according to the signal B6 of the logic high level, and the NOR gate NOR4 sets the switch modulation signal Fade_out to the logic high level according to the detection signal T1 of the logic low level and the signal B7. At time t3, the second count value CONT2 is equal to the first count value CONT1. When a falling edge of the clock signal CLK arrives, the logic unit 304 flips the output signal B4 from the logic low level to the logic high level. When a next rising edge of the clock signal CLK arrives, the D flip-flop 306 sets the switch modulation signal Fade_out to the logic low level. The second counter 303 continues to count the pulses of the clock signal CLK. When the second count value CONT2 reaches the second preset value (for example, equal to 100), the third detection signal T3 output by the third detection module 360 is flipped to the logic high level, the NOR gate NOR1 flips the signal B1 to the logic low level according to the third detection signal T3 of high level, the D flip-flop 305 and the second counter 303 are reset, and one switching period of the switch modulation signal Fade_out is finished. In a similar fashion, in the subsequent switch cycle, the second counter 303 and the logic output module 330 continue to repeat the above process.

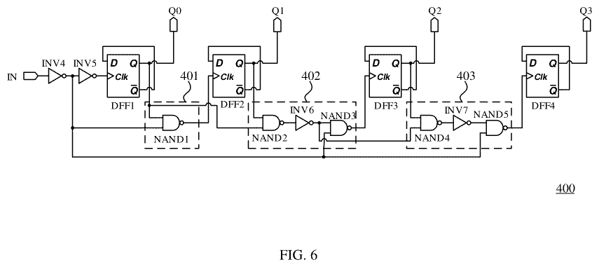

FIG. 6 shows a schematic circuit diagram of a synchronization counter according to an embodiment of the present invention. In the present embodiment, a key factor limiting the frequency of the clock signal CLK is counter delay. In traditional designs, the counter is a binary counter composed of a plurality of D flip-flops in series. If the number of bits output by the counter is large, then this delay will become a key factor limiting the frequency of the clock signal CLK. In order to minimize the delay, the present embodiment provides a new synchronization counter for the first counter 302 and the second counter 303, which greatly reduces the delay of the counter.

As shown in FIG. 6, the synchronization counter 400 of the present embodiment includes a plurality of D flip-flops DFF1-DFF4 (the present embodiment just takes four D flip-flops as an example, but the present disclosure is not limited by this) and a plurality of signal transfer units (as shown in FIG. 6, signal transfer units 401-403) located before the second D flip-flop DFF2 to the last D flip-flop DFF4 in the plurality of D flip-flops. Wherein, each signal transfer unit is configured to obtain a clock control signal for the D flip-flop connected thereto according to a logic state of a signal output Q of a previous D flip-flop and an inverse signal of a counting signal IN.

Specifically, the data signal inputs D of the plurality of D flip-flops DFF1˜DFF4 are connected to the signal outputs QN, the clock control terminals Clk are used to receive the clock control signal, and the signal outputs Q are used to output each bit <QOQ1Q2Q3>of the multi-bit binary count value, respectively.

Inverters INV4 and INV5 are connected in turn before the D flip-flop DFF1. An input terminal of the inverter INV4 is used to receive the counting signal IN, an output terminal is connected to an input terminal of the inverter INV5, and an output terminal of the inverter INV5 is connected to a clock control terminal Clk of the D flip-flop DFF1. Therefore, a waveform of the clock control signal of the D flip-flop DFF1 is the same as that of the counting signal IN.

The signal passing unit 401 includes, for example, a NAND gate NAND1. One input terminal of the NAND gate NAND1 receives a logic level of the signal output terminal Q of the D flip-flop DFF1, and the other input terminal receives an inverse signal of the counting signal IN, and an output terminal is connected to a clock control terminal Clk of the D flip-flop DFF2 to provide the clock control signal.

The signal transfer unit 402 includes, for example, a NAND gate NAND2, an inverter INV6, and a NAND gate NAND3. One input terminal of the NAND gate NAND2 is connected to the signal output terminal Q of the D flip-flop DFF2, the other input terminal of the NAND gate NAND2 is connected to the signal output terminal of the D flip-flop DFF1, an output terminal of the NAND gate NAND2 is connected to an input terminal of the inverter INV6, an output terminal of the inverter INV6 is connected to one input terminal of the NAND gate NAND3, the other input terminal of the NAND gate NAND3 is connected to the inverse signal of the counting signal IN, and an output terminal of the non-gate NANB6 is connected to a clock control terminal of the D flip-flop DFF3. Wherein, the signal transfer unit 402 is configured to perform a NAND logical operation on output signals of the D flip-flops DFF1 and DFF2. An operation result signal is inverted by the inverter INV6 and then perform a NAND logical operation with the inverse signal of the counting signal IN, so that the clock control signal of the D flip-flop DFF3 is obtained.

The signal transfer unit 403 includes, for example, a NAND gate NAND4, an inverter INV7, and a NAND gate NAND5. One input terminal of the NAND gate NAND4 is used to receive a logical operation result of output signals of the D flip-flops DFF1 and DFF2, the other input terminal receives an output signal of the D flip-flop DFF3, and an output terminal is connected to an input terminal of the inverter INV7. One input terminal of the NAND gate NAND5 is connected to an output terminal of the inverter INV7, the other input terminal is connected to the inverse signal of the counting signal IN, and an output terminal is connected to a clock control terminal of the D flip-flop DFF4. Wherein, the NAND gate NAND4 is used to perform logical a NAND logical operation on an AND logical operation result of the output signals of the D flip-flops DFF1 and DFF2 and the output signal of the D flip-flop DFF3. An obtained result is inverted by the inverter INV7 to obtain an AND logical operation result of the output signals of the D flip-flops DFF1 to DFF3. Then a NAND logical operation is performed on the AND logical operation result and the inverse signal of the counting signal IN, so that the clock control signal of the D flip-flop DFF4 is obtained.

In summary, by setting the signal transfer unit, before the clock control signal is sent to each D flip-flop in the counter, the synchronization counter provided in the present embodiment can prejudge whether output signal of all D flip-flops before this D flip-flop is at a logic high level. If the output signal of all D flip-flops before the D flip-flop is at the logic high level, the clock control signal for controlling this D flip-flop is the same as the counting signal, and conversely, the clock control signal of this D flip-flop is set to the logic high level, so that the output delay of the counter could be only a delay of one D flip-flop, and the delay of the counter is greatly reduced.

In summary, the audio power amplifier circuit of the embodiment of the present disclosure includes a high frequency switch and a duty cycle modulation circuit arranged between the input resistors of the second-stage integral amplifier of the integral amplifier module. During the process of turning on or off the chip, the duty cycle modulation circuit generates a switch modulation signal of the high frequency switch by counting the duty cycle modulation signal and the clock signal, so that the duty cycle of the high frequency switch could be gradually reduced or increased according to a set linearity, so as to regulate the gain of the audio power amplifier circuit. Not only the “pop” noise could be weakened, but also the linearity of the circuit could be improved, and the cost of the circuit could be reduced.

In a further embodiment, the present disclosure further provides a synchronization counter for counting. By setting the signal transfer unit, before the clock control signal is sent to each D flip-flop in the counter, the counter can prejudge whether output signal of all D flip-flops before this D flip-flop is at a logic high level. If the output signal of all D flip-flops before the D flip-flop is at the logic high level, the clock control signal for controlling this D flip-flop is the same as the counting signal, and conversely, the clock control signal of this D flip-flop is set to the logic high level, so that the output delay of the counter could be only a delay of one D flip-flop, and the delay of the counter is greatly reduced.

It will be appreciated by those of ordinary skill in the art that the words “during”, “when”, and “at this time” used herein in connection with circuit operation are not strict terms for actions that occur immediately at a beginning of a start action, but that there may be some small but reasonable one or more delays after a reaction action initiated by a start action, such as various transmission delays, etc. As used herein, the word “approximately” or “substantially” means an element has a parameter that is expected to approximate the declared value or location. However, as is well known in the art, there are always minor deviations that make it difficult to have the value or position to be strictly the declared value. It has been properly determined in the art that a deviation of at least ten percent (10%) is a reasonable deviation from the precise desired target described (for a doping concentration of semiconductor, at least twenty percent (20%)). When a signal is described with a state, an actual voltage value or logic state of the signal (e.g. “1” or “0”) depends on whether positive or negative logic is used.

Furthermore, it should be noted that relational terms such as first and second, etc., in this document are merely used to distinguish one entity or operation from another entity or operation, but do not necessarily require or imply any actual relationship or order between these entities or operations. Furthermore, the word “include”, “contain”, or any other variation thereof is intended to cover non-exclusive inclusion, so that a process, method, article, or device including a series of elements includes not only those elements, but other elements that are not explicitly listed or elements inherent to such process, method, article, or device. In the absence of further limitations, elements defined by the phrase “comprises a . . . ” do not exclude the presence of additional identical elements in the process, method, article, or device that includes the elements. Moreover, in the description of the invention, unless otherwise stated, the meaning of “a plurality” is two or more.

In accordance with embodiments of the present disclosure, such as those described above, these embodiments do not describe all details in detail, nor do they limit the invention to specific embodiments only. Obviously, a lot of modifications and changes can be made based on the above description. These embodiments are selected and specifically described in this specification in order to better explain the principles and practical applications of the present disclosure, so that those skilled in the art can make good use of the present disclosure and its modifications on the basis of the present disclosure. The scope of protection of the present disclosure shall be subject to the scope defined in the claims of the present disclosure.

1. A duty cycle modulation circuit of an audio power amplifier circuit, wherein the audio power amplifier circuit comprises an integral amplifier module and a high frequency switch disposed between input resistors of a second-stage integral amplifier in the integral amplifier module, the duty cycle modulation circuit is configured to adjust a gain of the audio power amplifier circuit by controlling a duty cycle of the high frequency switch,
and the duty cycle modulation circuit comprises:
a first counting module for counting pulses of a duty cycle modulation signal to obtain a first count value;
a second counting module for counting pulses of a clock signal to obtain a second count value; and
a logic output module for performing a logical operation according to the first count value, the second count value, and the clock signal to obtain a switch modulation signal for controlling the high frequency switch.

2. The duty cycle modulation circuit according to claim 1, wherein the logic output module is configured to determine a pulse width of the switch modulation signal according to the first count value and to determine a switching period of the switch modulation signal according to the second count value.

3. The duty cycle modulation circuit according to claim 1, further comprising:
a first detection module for providing a first detection signal to the logic output module upon the first count value is 0,
the logic output module for setting the switch modulation signal to an initial level state according to the first detection signal.

4. The duty cycle modulation circuit according to claim 3, further comprising:
a second detection module for providing a second detection signal to the first counting module and the logic output module upon the first counting value reaches a first preset value,
the first counting module stopping counting the pulses of the duty cycle modulation signal according to the second detection signal, and the logic output module setting the switch modulation signal in a final level state according to the second detection signal.

5. The duty cycle modulation circuit according to claim 4, further comprising:
a third detection module for outputting a third detection signal upon the second count value reaches a second preset value; and
a first NOR gate for performing a NOR logical operation on the third detection signal and the first detection signal, and providing a first logical signal to the second counting module,
wherein the first NOR gate is configured to reset the second counting module upon one of the first detection signal and the third detection signal is valid.

6. The duty cycle modulation circuit according to claim 5, wherein the first counting module comprises:
a first D flip-flop having a first data signal input terminal, a first clock control terminal, a first reset terminal and a first signal output terminal, wherein the first data signal input terminal receives the duty cycle modulation signal, the first clock control terminal receives the clock signal, the first reset terminal receives a reset signal, and the first signal output terminal outputs a second logic signal;
a second NOR gate for performing a NOR logical operation on the second detection signal, the second logic signal, and an inverse signal of the reset signal, and outputting a third logic signal; and
a first counter having a second clock control terminal, a second reset terminal and a second signal output, wherein the second clock control terminal receives the third logic signal, the second reset terminal receives the reset signal, and the second signal output outputs the first count value.

7. The duty cycle modulation circuit according to claim 6, wherein the second counting module comprises:
a second counter having a third clock control terminal, a third reset terminal and a third signal output, wherein the third clock control terminal receives the clock signal, the third reset terminal receives the first logic signal, and the third signal output outputs the second count value.

8. The duty cycle modulation circuit according to claim 5, wherein the logic output module comprises:
a logic unit having a first count input terminal, a second count input terminal, a fourth clock control terminal, a fourth reset terminal and a fourth signal output terminal, wherein the first count input receives the first count value, the second count input receives the second count value, the fourth clock control terminal receives the clock signal, the fourth reset terminal receives the reset signal, and the fourth signal output terminal outputs a fourth logic signal;
a second D flip-flop having a second data signal input terminal, a fifth clock control terminal, a fifth reset terminal and a fifth signal output terminal, wherein the second data signal input terminal receives a power supply voltage, the fifth clock control terminal receives the fourth logic signal, the fifth reset terminal receives the first logic signal, and the fifth signal output terminal outputs a fifth logic signal;
a third D flip-flop having a third data signal input terminal, a sixth clock control terminal, a sixth reset terminal, and a sixth signal output terminal, wherein the third data signal input terminal receives the fifth logic signal, the sixth clock control terminal receives the clock signal, the sixth reset terminal receives an inverse signal of the first detection signal, and the sixth signal output terminal outputs a sixth logic signal;
a third NOR gate for performing a NOR logical operation on the second detection signal and the sixth logic signal, and outputting a seventh logic signal; and
a fourth NOR gate for performing a NOR logical operation on the first detection signal and the seventh logic signal, and outputting the switch modulation signal.

9. The duty cycle modulation circuit according to claim 8, wherein the logic unit is configured to determine whether the first count value is equal to the second count value before each falling edge of the clock signal comes, and if so, set the fourth logic signal to a logic high level.

10. The duty cycle modulation circuit according to claim 7, wherein the first count value and the second count value are constituted by a multi-bit binary number, and the first counter and the second counter includes a synchronous counter.

11. The duty cycle modulation circuit according to claim 10, wherein the synchronization counter comprises:
a plurality of D flip-flops having the same number as bits of the multi-bit binary number, a clock control terminal of a first D flip-flop of the plurality of D flip-flops receiving a counting signal; and
a plurality of signal transfer units preceding a second to last D flip-flop of the plurality of D flip-flops,
wherein each signal transfer unit is configured to obtain a signal of a clock control terminal of a corresponding D flip-flop according to an output logic state of the D flip-flop before the corresponding D flip-flop and an inverse signal of the counting signal.

12. The duty cycle modulation circuit according to claim 11, wherein each signal transfer unit is configured to:
determining whether the output logic state of all D flip-flops before the corresponding D flip-flop is at a logic high level, and if so, controlling the signal of the clock control terminal of the corresponding D flip-flop to be the same as the counting signal; otherwise, controlling the signal of the clock control terminal of the corresponding D flip-flop is constantly at the logic high level.

13. The duty cycle modulation circuit according to claim 12, wherein the signal transfer unit comprises at least one NAND gate or a combination of at least one NAND gate and an inverter.

14. The duty cycle modulation circuit according to claim 1, wherein a frequency of the clock signal is set by a frequency of the switch modulation signal and a duty cycle change linearity required by the system.

15. The duty cycle modulation circuit according to claim 1, wherein a frequency of the duty cycle modulation signal is set by a chip power on or off time.

16. A noise suppression circuit for an audio power amplifier circuit, wherein the audio power amplifier circuit comprises at least an integral amplifier module, a signal modulation module, and a drive output module, and the noise suppression circuit comprises:
a high frequency switch disposed between input resistors of a second-stage integral amplifier in the integral amplifier module; and
the duty cycle modulation circuit according to claim 1 for adjusting a gain of the audio power amplifier circuit by controlling a duty cycle of the high frequency switch.

17. An audio power amplifier circuit, comprising:
an integral amplifier module comprising at least a first-stage operational amplifier and a second-stage integral amplifier, for amplifying a differential input signal by an integration operation to obtain a differential output signal;
a signal modulation module for generating a first pulse width modulation signal and a second pulse width modulation signal according to the differential output signal;
a drive output module for amplifying the first pulse width modulation signal and the second pulse width modulation signal, respectively, so as to obtain a drive signal for driving a speaker;
a high frequency switch disposed between input resistors of the second-stage integral amplifier in the integral amplifier module; and
the duty cycle modulation circuit according to claim 1 for adjusting a gain of the audio power amplifier circuit by controlling a duty cycle of the high frequency switch.
